(19) United States
(12) Patent Application Publication
(10) Pub. No.: US 2017/0228191 A1
(43) Pub. Date: Aug. 10, 2017

(54) SYSTEMS AND METHODS FOR SUPPRESSING LATENCY IN NON-VOLATILE SOLID STATE DEVICES

(71) Applicant: Western Digital Technologies, Inc., Irvine, CA (US)

(72) Inventors: Chao SUN, San Jose, CA (US); Seung-Hwan SONG, San Jose, CA (US); Minghai QIN, San Jose, CA (US); Zvonimir Z. BANDIC, San Jose, CA (US)

(21) Appl. No.: 15/018,010

(22) Filed: Feb. 8, 2016

(51) Int. Cl. G06F 3/06; G11C 16/26; G06F 12/02; G11C 16/16

(52) U.S. Cl. CPC G06F 3/0647; G11C 16/16; G11C 16/26; G06F 3/0611; G06F 3/0652; G06F 3/0685; G06F 12/0246; G06F 12/0253; G06F 2212/1044; G06F 2212/1024; G06F 2212/2022; G06F 2212/7205

(57) ABSTRACT

Methods and systems for suppressing the latency in a non-volatile memory are provided. The non-volatile memory can include a flash memory and a storage class memory. The storage class memory can be divided in a first region and a second region. A method for suppressing the latency in the non-volatile memory can determine whether a received host command requires access to the flash memory. When the host command does not require access to the flash memory, the method can further determine whether the host command requires access to the first region or the second region of the storage class memory. The method can suppress the latency in the non-volatile memory by copying valid pages of flash memory blocks into the storage class memory.

### FIELD OF THE DISCLOSURE

The present disclosure relates to systems and methods for suppressing the latency in a non-volatile solid state device (“SSD”) and specifically for suppressing the worst input-output (IO) latency of NAND flash-based SSDs.

### RELATED DISCLOSURE

During operation of a non-volatile solid state device (“SSD”), garbage collection (“GC”) can be performed to generate and maintain free memory blocks in the SSD. The free blocks contain free pages that are available for writing new data. The free blocks can be reclaimed from memory blocks that can contain both valid and invalid data. During the garbage collection operation, a block is first identified for reclaiming, e.g., a “victim” block. Any valid pages residing in the victim block are copied to another memory block, and the entire victim block is erased. The garbage collection operation uses read and write operations, in addition to the erase operation. These operations can compete with host user read and write operations for access to the same memory blocks.

In a NAND flash-based SSD, a read/write operation occurs on a particular page of a block, while an erase operation occurs on the entire block. Pages of a particular block can be written at any time if they are free, e.g., had been previously erased. For example, new pages can be written to a block, if the block has currently free pages. Data in some pages of the block can become invalid, e.g., stale, and can be replaced with valid data. Replacement pages with valid data cannot override pages with invalid data; rather they can be written to the block in other free pages. As discussed above, during garbage collection, pages of a first block with valid data are read from the block (victim block) and are written to a new block. Then the entire victim block can be erased. Garbage collection can result in inconsistent performance of a NAND flash-based SSD, e.g., the worst IO latency happens when garbage collection occurs in an SSD, and the host needs to wait for the garbage collection to complete before it can read or write data to the SSD.

Accordingly, efficient ways to perform garbage collection are desirable that can suppress the worst IO latency in a NAND flash-based SSD.

### SUMMARY

The present disclosure relates to methods and systems for suppressing the worst input-output (IO) latency in NAND flash-based SSDs.

One embodiment can include a method for reducing latency in a non-volatile memory that includes a flash memory and a storage class memory. The method can include the steps of providing a first region and a second region in the storage class memory, receiving by the non-volatile memory a first command from a host in communication with the non-volatile memory, and determining whether the first command requires access to a block in the flash memory. When the first command does not require access to the block in the flash memory, the method can further determine whether the first command requires access to the second region in the storage class memory. When the first command requires access to the second region in the storage class memory, the method can move data accessed by the first command from the second region in the storage class memory to the first region in the storage class memory.

According to embodiments of the present invention, when the first command does not require access to the second region in the storage class memory, a method for reducing latency in a non-volatile memory can further access the first region in the storage class memory to execute the first command and evict data from the second region in the storage class memory to the flash memory.

According to embodiments of the present invention, when the first command requires access to the block in the flash memory, a method for reducing latency in a non-volatile memory can determine whether a garbage collection operation is executed in the flash memory and, when the garbage collection operation is not executed, determine whether the flash memory is in an idle state and evict data from the second region in the storage class memory to the flash memory, when the flash memory is in the idle state.

According to embodiments of the present invention, when the flash memory is not in the idle state, a method for reducing latency in a non-volatile memory can further determine whether the first command is at least one of a read command and a write command, and, when the first command is a write command, the method can evict a data page from the second region in the storage class memory to the flash memory, and execute the write command. When the first command is a read command, the method can execute the read command and evict two data pages from the second region in the storage class memory to the flash memory.

According to embodiments of the present invention, when the garbage collection operation is executed, a method for reducing latency in a non-volatile memory can copy valid pages from a first flash memory chip to the second region of the storage class memory and erase a memory block in the first flash memory chip. The method can further determine that at least one of the garbage collection operation is not executed on the first flash memory chip and the second region of the storage class memory has data from the first flash memory chip and evict data from the first flash memory chip to the second region in the storage class memory.

According to embodiments of the present invention, a method for reducing latency in a non-volatile memory can evict data from the second region of the storage class memory to the flash memory based on an eviction policy based on at least one of the number of pages in a block in the second region and the age of the pages in the block in the second region.

Another embodiment can include a system for reducing latency in a non-volatile memory that comprises a flash memory, a storage class memory, comprising a first region and a second region, and a memory controller in communication with a host, the flash memory, and the storage class memory. The memory controller can be configured to receive a first command from the host and determine whether the first command requires access to a block in the flash memory. When the first command does not require access to the block in the flash memory, the memory controller can further determine whether the first command requires access to the second region in the storage class memory. When the first command requires access to the second region in the storage class memory, the memory controller can further move data accessed by the first command from the second region in the storage class memory to the first region in the storage class memory.

According to embodiments of the present invention, when the first command does not require access to the second region in the storage class memory, the memory controller can further access the first region in the storage class memory to execute the first command and evict data from the second region in the storage class memory to the flash memory.

According to embodiments of the present invention, when the first command requires access to the block in the flash memory, the memory controller can determine whether a garbage collection operation is executed in the flash memory and, when the garbage collection operation is not executed, determine whether the flash memory is in an idle state and evict data from the second region in the storage class memory to the flash memory, when the flash memory is in the idle state.

According to embodiments of the present invention, the memory controller can further determine whether the first command is at least one of a read command and a write command, when the flash memory is not in the idle state. When the first command is a write command, the memory controller can evict a data page from the second region in the storage class memory to the flash memory and execute the write command.

According to embodiments of the present invention, when the first command is a read command, the memory controller can execute the read command and evict two data pages from the second region in the storage class memory to the flash memory.

According to embodiments of the present invention, when the garbage collection operation is executed, the memory controller can copy valid pages from a first flash memory chip to the second region of the storage class memory and erase a memory block in the first flash memory chip.

According to embodiments of the present invention, the memory controller can determine that at least one of the garbage collection operation is not executed on the first flash memory chip and the second region of the storage class memory has data from the first flash memory chip and evict data from the first flash memory chip to the second region in the storage class memory.

According to embodiments of the present invention, the memory controller can evict data from the second region of the storage class memory to the flash memory based on an eviction policy based on at least one of the number of pages in a block in the second region and the age of the pages in the block in the second region.

### BRIEF DESCRIPTION OF THE DRAWINGS

Various objects, features, and advantages of the present disclosure can be more fully appreciated with reference to the following detailed description when considered in connection with the following drawings, in which like reference numerals identify like elements. The following drawings are for the purpose of illustration only and are not intended to be limiting of the invention, the scope of which is set forth in the claims that follow.

FIG. 1 illustrates an exemplary scenario of a worst IO latency in a NAND flash-based SSD, according to aspects of the disclosure.

FIG. 2 shows the impact of garbage collection to the SSD performance and latency, according to aspects of the disclosure.

FIG. 3 shows an exemplary SSD structure, according to aspects of the disclosure.

FIG. 4 shows an exemplary Storage Class Memory (“SCM”) architecture, according to aspects of the disclosure.

FIG. 5 shows an exemplary SCM region structure, according to aspects of the disclosure.

FIGS. 6A-D show exemplary SSD operations during garbage collection, according to aspects of the disclosure.

FIG. 7 shows a comparison of the garbage collection latency overhead of a conventional system and a proposed system, according to aspects of the disclosure.

FIG. 8 shows exemplary data page eviction policies, according to aspects of the disclosure.

FIG. 9 shows an exemplary flow chart of a method for reducing worst case latency of NAND flash-based SSDs, according to aspects of the disclosure.

### DETAILED DESCRIPTION

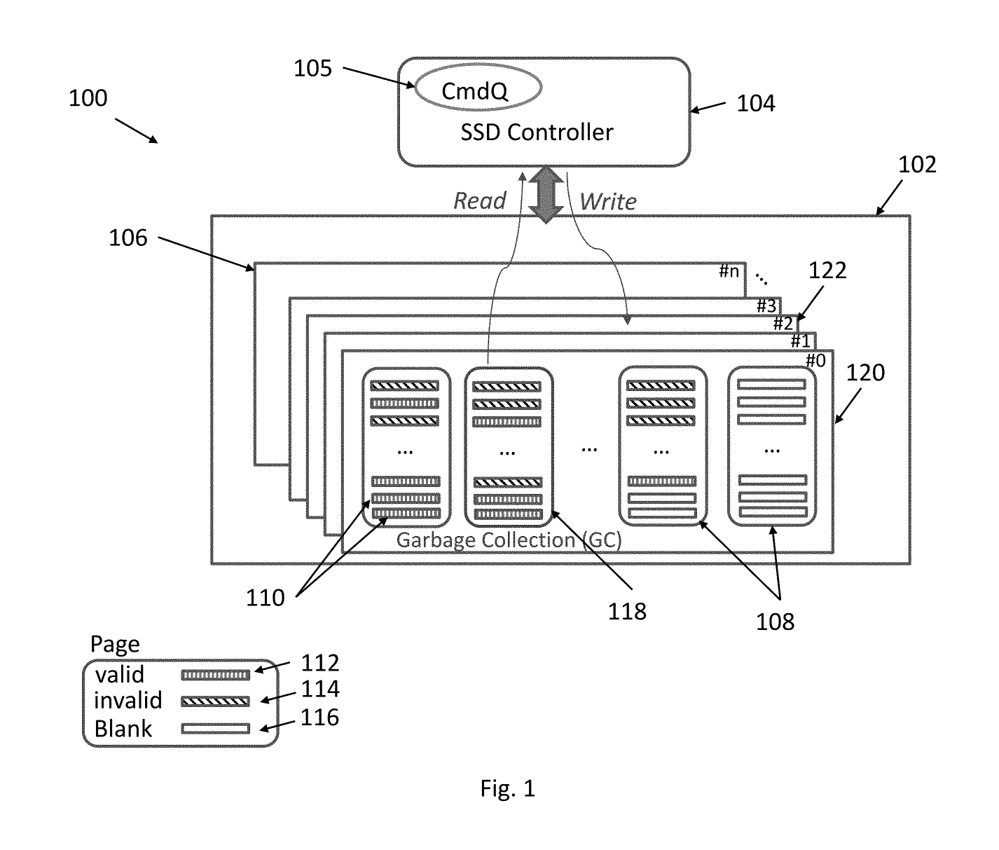

Systems and methods for suppressing the worst input-output (IO) latency of NAND flash-based SSDs are provided. The worst IO latency in a NAND flash-based SSD occurs when the host controller has issued a command, e.g., a read or a write command, for a particular page in a block that undergoes garbage collection. When this happens, the host controller waits for the garbage collection operation to complete, before the command can operate on the particular page. FIG. 1 illustrates an exemplary scenario 100 of a worst IO latency. Specifically, FIG. 1 shows SSD memory 102 in communication with SSD memory controller 104. A person skilled in the art would understand that the memory controller can be a component of the SSD. Memory controller 104 can have one or more command queues that can include commands from the host and/or internal requests generated by SSD controller. In the example of FIG. 1, SSD memory controller 104 includes a single command line CmdQ 105. SSD memory 102 can include one or more NAND flash chips 106. In the example of FIG. 1, SSD memory 102 includes “n+1” NAND flash chips 106. Each NAND flash chip 106 can have multiple blocks 108, and each block can have multiple pages 110. Each page can have either valid data 112 or invalid data 114 or be blank 116, e.g., previously erased. FIG. 1 shows that a garbage collection operation happens for block 118 of NAND flash chip #0 (120). During garbage collection, the SSD controller 104 reads the valid pages in block 118, e.g., the victim block, and writes them in another block, e.g., a destination block. The destination block can be located in the same NAND flash chip #0 (120) or can be located in a different NAND flash chip. In the example of FIG. 1, the destination block is located in NAND flash chip #2 (122). After the valid blocks have been written to the destination block, the victim block is erased, and new pages can be written into it. Accordingly, the worst latency T_{CMD}_{_}_{WAIT} the host controller suffers is the latency T_{GC} for the garbage collection operation to complete.

T_{CMD}_{_}_{WAIT}=T_{GC}≅T_{E}+γ(T_{RD}+T_{WR}),

where T_{E} is the block erase latency, T_{RD} is the page read latency, T_{WR} is the page write latency, and “γ” is the number of valid pages in the block that need to be read from the block and written to another block before the block is erased. Typically in NAND flash memories, a write operation is longer than a read operation. Assuming that the NAND flash has a read latency T_{RD} of 50 μs per a 16 KB page size, a write latency T_{WR} of 1 ms per a 16 KB page size, an erase latency of 3 ms per block, and a valid page ratio is 10%, e.g., γ=25 pages in a block of 256 pages, the latency to reclaim a block is T_{CMD}_{_}_{WAIT}=3 ms+25*(50 μs+1 ms)=29.25 ms. The garbage collection can be an atomic operation, where all the valid pages from the victim block are migrated to another block, since the objective of copying the pages is to reclaim the block by erasing it. The garbage collection operation can also be pre-emptive in case of a read operation. In this case, the control algorithm can be more complicated to address different scenarios. For example, if one of the pages in the reclaiming block is read-intensive followed by a write request, then the write request can wait for all the read requests to complete.

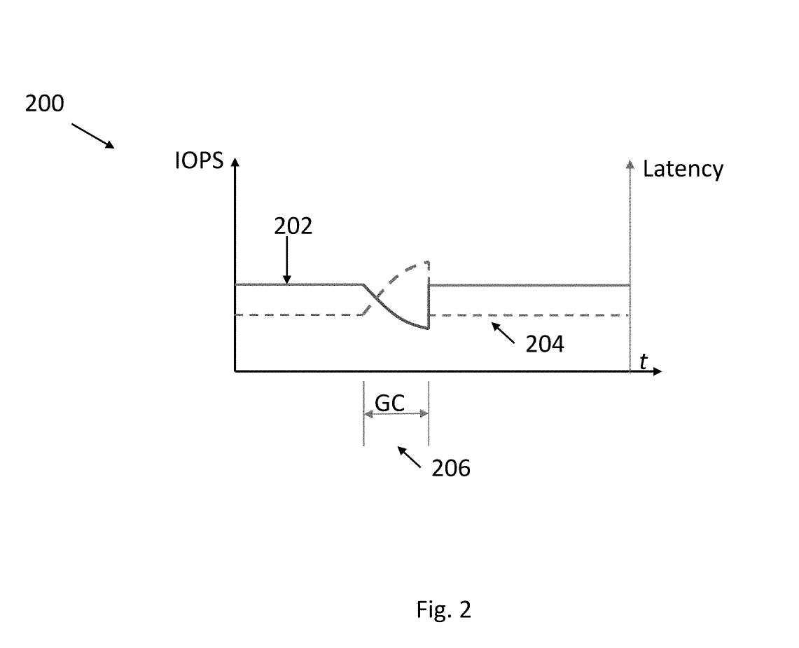

Therefore, the latency during garbage collection increases until the garbage collection operation completes. The latency and the performance of the SSD are related. Accordingly, during garbage collection, the performance of the SSD is also degraded. This is illustrated in FIG. 2, which shows a graph 200 that demonstrates the effect of garbage collection to IOPS and latency of a SSD. Input/Output Operations Per Second (“IOPS”) is a common performance measurement that can benchmark SSD performance. Specifically, FIG. 2 shows how IOPS 202 and latency 204 vary when a garbage collection operation takes place 206. During garbage collection 206, IOPS 202 drop, while latency 204 increases. When the garbage collection operation completes, both IOPS 202 and latency 204 reach their normal values. This results in inconsistent performance for the SSD. The frequency of garbage collection operation depends on SSD characteristics, such as over-provisioning, data management algorithms, and workloads.

Different prior art approaches attempt to reduce the garbage collection overhead. Some attempt to reduce the garbage collection overhead by increasing the over-provisioning area. However, these prior art attempts increase the NAND flash cost, without completely eliminating the worst case latency. Other prior art approaches use Dynamic Read Access Memory (“DRAM”) or Storage Class Memory (“SCM”) cache buffers to absorb hot, e.g., frequently accessed, writes or classify data activity, e.g., classify data as hot or cold, and store data of similar activity in the same block. These approaches can decrease the garbage collection frequency, however, they cannot eliminate the worst garbage collection latency, which is especially true in case of reclaiming blocks with many cold data. Other prior art approaches write small data to fragmented NAND flash pages by scrambling the logical block addresses (LBA). These approaches can reduce the garbage collection latency, however, they need to maintain a very large table for logical block addressing, which makes them impractical for commercial products.

The disclosed systems and methods suppress the worst case garbage collection latency, which can result in a consistent performance of an SSD. A solid-state storage device uses integrated circuit assemblies as memory to store data persistently. For example, an SSD can include one or more integrated circuits of one type of memory, for example, NAND-flash memory, or can include more than one types of non-volatile memory. According to aspects of the disclosure, the proposed systems and methods use a hybrid NAND flash memory with Storage Class Memory. Storage is often thought of as a mechanical hard disk drive (“HDD”) that offers near limitless capacity, when compared to DRAM. It is also persistent, which means that information is not lost if the server crashes or loses power. The problem with hard drives is that in many cases they are unable to provide information to the application quickly enough.

Storage Class Memory (“SCM”), such as Magnetoresistive Random-Access Memory (“MRAM”), Phase-Change Memory (“PCM”), Resistive random-access memory (“ReRAM”), and a battery-backed DRAM, is a class of storage/memory devices that can provide an intermediate step between high-performance DRAM and cost-effective HDDs. SCMs have much larger endurance than NAND flash memories. SCM is byte-addressable, in comparison to NAND flash, which operates in page unit (4 KB-16 KB). SCMs can blur the distinction between memory devices, which can be fast, expensive, and volatile, and storage devices, which can be slow, cheap, and non-volatile, and combine the benefits of both to be low-cost, fast, and non-volatile. SCMs can provide read performance similar to DRAM and write performance that is significantly faster than HDD technology.

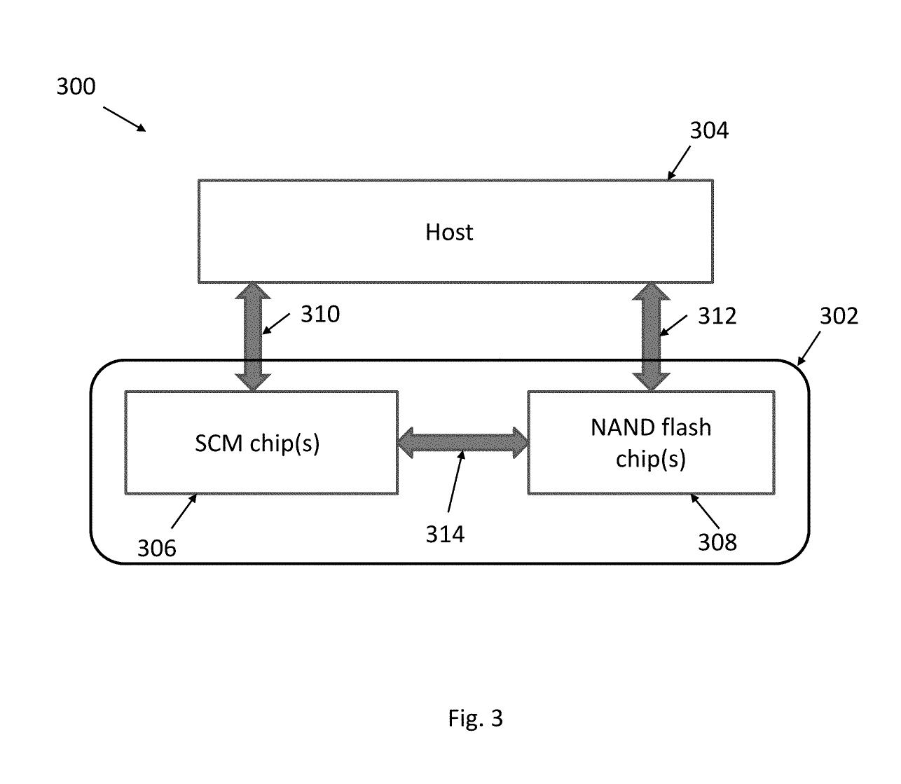

The disclosed hybrid NAND flash memory/SCM SSD combines the benefit of an in-place update non-volatile memory as well as the benefit of a block-erasable non-volatile memory. An exemplary architecture 300 of a hybrid NAND flash memory/SCM SSD in communication with a host is illustrated in FIG. 3. Specifically, FIG. 3 shows SSD 302 in communication with host 304. SSD 302 can include one or more SCM chips 306 and one or more NAND flash chips 308. Host 304 can communicate with SCM chips 306 through communication channel 310 and with NAND flash chips 308 through communication channel 312. SCM chips 306 and NAND flash chips 308 can communicate through communication channel 314.

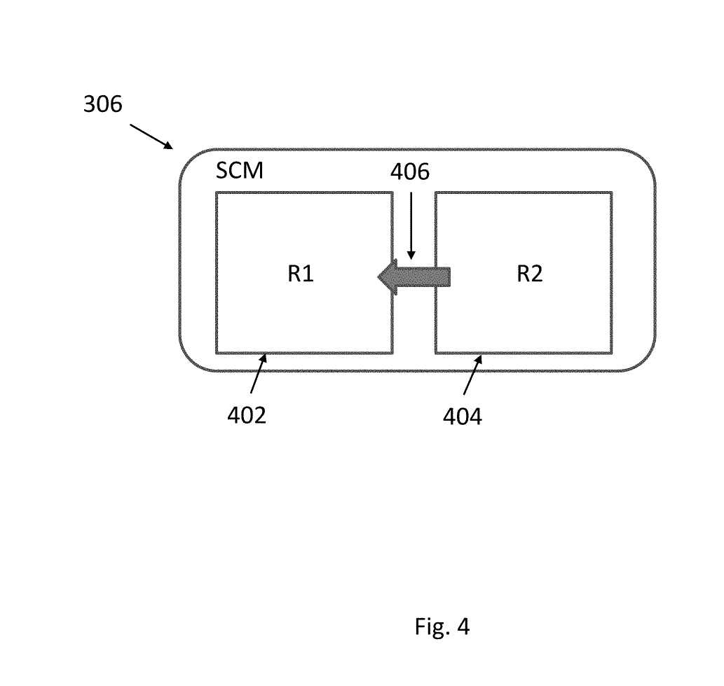

According to aspects of the disclosure, the SCM chips 306 can be divided into two regions. This is illustrated in FIG. 4. Specifically, FIG. 4 shows SCM chips 306 logically divided into a first region R1 (402) and a second region R2 (404). The first region R1 (402) can be used to store frequently accessed data (hot data). For example, the first region R1 (402) can be used as a cache/buffer, or a storage space, depending on whether the SCM is used as a partly replacement of DRAM or as storage. The second region R2 can be reserved for reducing the garbage collection overhead for the NAND flash memory. According to the exemplary embodiment disclosed in FIG. 4, when the host requests data stored in the second region R2 (404), the requested data can be moved from the second region R2 (404) to the first region R1 (402), before they are made available to the host. The first region R1 can be logically differentiated from the second region R2. The ratio of the size of the first region R1 over the size of the second region R2 can be adjusted dynamically, for example, by a firmware algorithm.

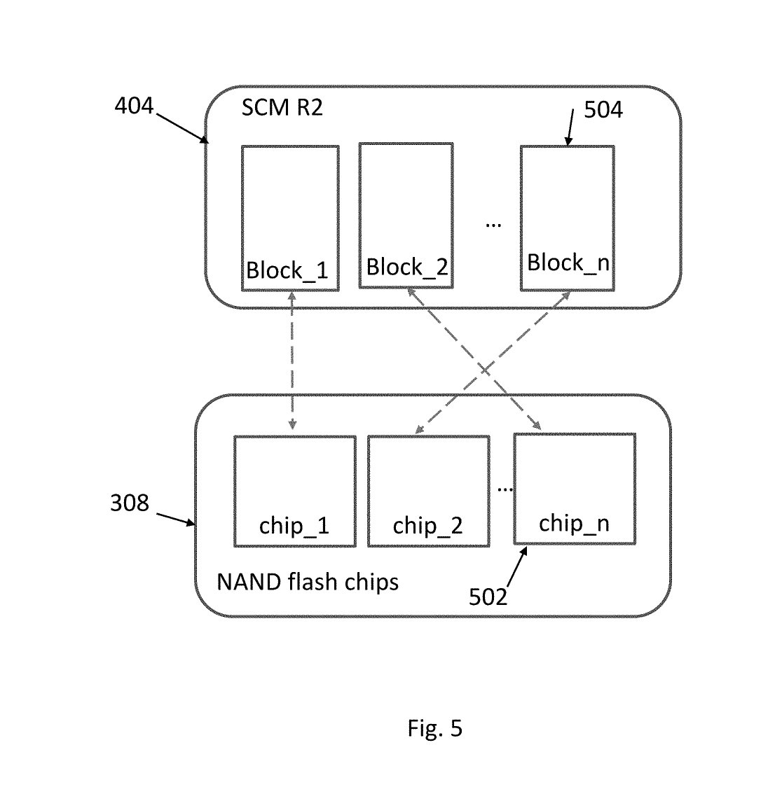

According to aspects of the disclosure, FIG. 5 shows an exemplary structure for the second region R2 (404) of SCM chips 306. Specifically, FIG. 5 shows second region R2 (404) and NAND flash chips 308. In some embodiments, there are n NAND flash chips 502 that can operate in parallel in the form of a multichannel and multiway memory. Within each NAND flash chip 502 there can be multiple blocks. According to aspects of the disclosure, the second region R2 (404) can be arranged to include n blocks 504. The size of the second region R2 blocks can be equal to the product of the number of the recycled blocks in the NAND flash chip 502 times the NAND flash chip block size. The number of recycled blocks in a NAND flash chip 502 can be a parameter in SSD controller firmware. The size of the second region R2 can be selected according to a particular product or a particular application. According to aspects of the disclosure, the size of the first region R1 and the size of the second region R2 can be dynamically adjusted, while the total SCM size is fixed. Each block 504 in the second region R2 (404) can be associated with a particular NAND flash chip 502. During garbage collection, data can be copied from a NAND flash chip 502 to its associated block 504 in the second region R2 (404). In addition, during the second region R2 eviction phase, a data page from a block in the second region R2 (404) can be copied to any NAND flash chip 502. However, because the SCM is non-volatile, there is no requirement to copy the data back to the NAND flash immediately. The data page to evict from the second region R2 (404) can be determined based on an eviction policy, which is discussed below.

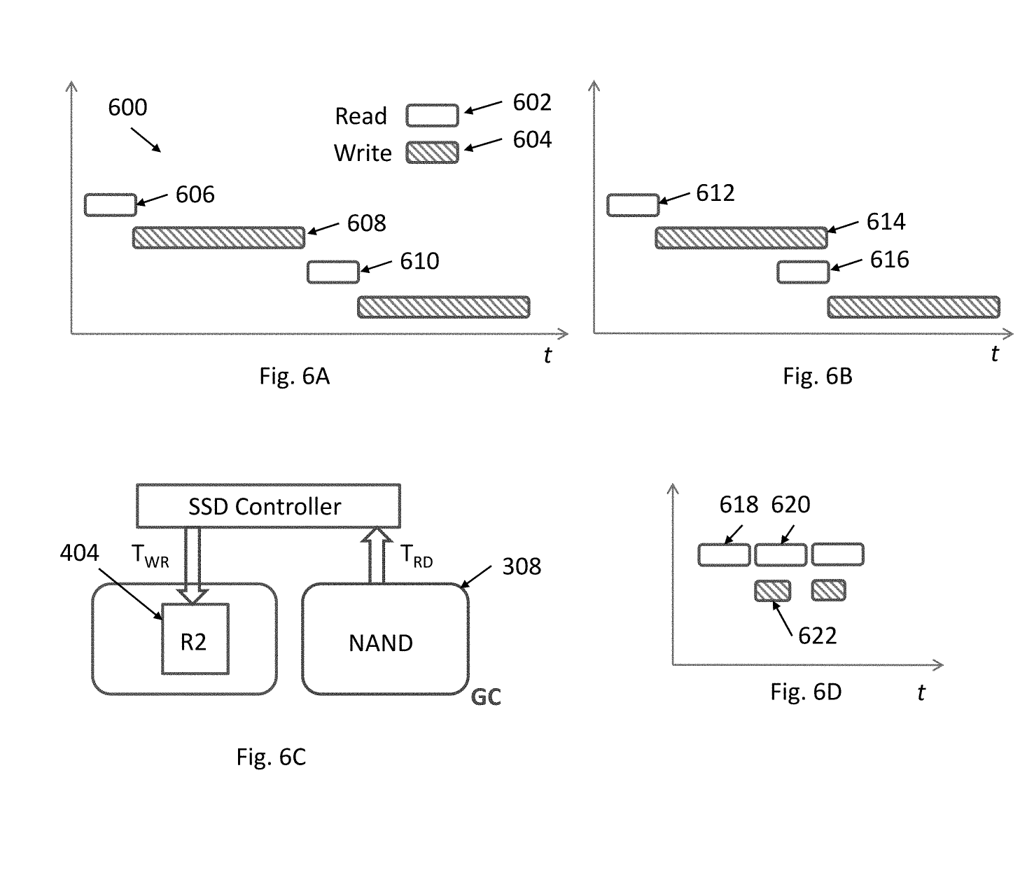

According to aspects of the disclosure, the latency reduction during garbage collection based on the proposed systems and methods are illustrated in FIGS. 6A-D. Specifically, FIGS. 6A-B show prior art methods for reading a page 602 from a first block and writing the page 604 to a destination block. In FIG. 6A, a first page is read 606 from the first block and the page is written 608 to a destination block. In the example of FIG. 6A, the first block and the destination block are located on the same NAND flash chip, and, accordingly, the second page can be read 610 only after the writing of the first page 608 completes.

If the destination block is located on a different NAND chip, then the second page can be read before the first page is written on the destination block. This is illustrated in FIG. 6B, where a first page is read 612 from the first block of a first NAND flash chip and is written 614 to a destination block in a different NAND flash chip. Therefore, the second page from the first block can be read 616 before the writing operation 614 of the first page completes.

According to aspects of the disclosure, during garbage collection, the valid pages from the victim block in NAND flash 308 can be copied to the second region R2 (404) of SCM 306, as illustrated in FIG. 6C. The SCM 306 write time T_{WR} can be fast, e.g., faster than the read time T_{RD} from the NAND flash. This is illustrated in FIG. 6D. When the first read 618 from NAND flash 308 completes, a second read 620 can start, and at the same time the page from the first read 618 can be written 622 to the second region R2 (404) of the SCM, because the write time to the SCM is shorter than the read time from the NAND flash memory. In this case, the worst latency T_{CMD}_{_}_{WAIT} the host controller suffers is given by the next equation:

T_{CMD}_{_}_{WAIT}=T_{GC}≅T_{E}+γ(T_{RD}),

where T_{E} is the block erase latency, T_{RD} is the page read latency, and γ is the number of valid pages in the block that is being erased. Assuming, that the NAND flash has read latency T_{RD} of 50 μs per a 16 KB page size, erase latency of 3 ms per block, and a valid page ratio of 10%, e.g., γ=25 pages in a block of 256 pages, the latency to reclaim a block according to the proposed system is T_{CMD}_{_}_{WAIT}=3 ms+25*50 μs=4.25 ms, significantly reduced from the latency value of 29.25 ms of a conventional NAND flash memory.

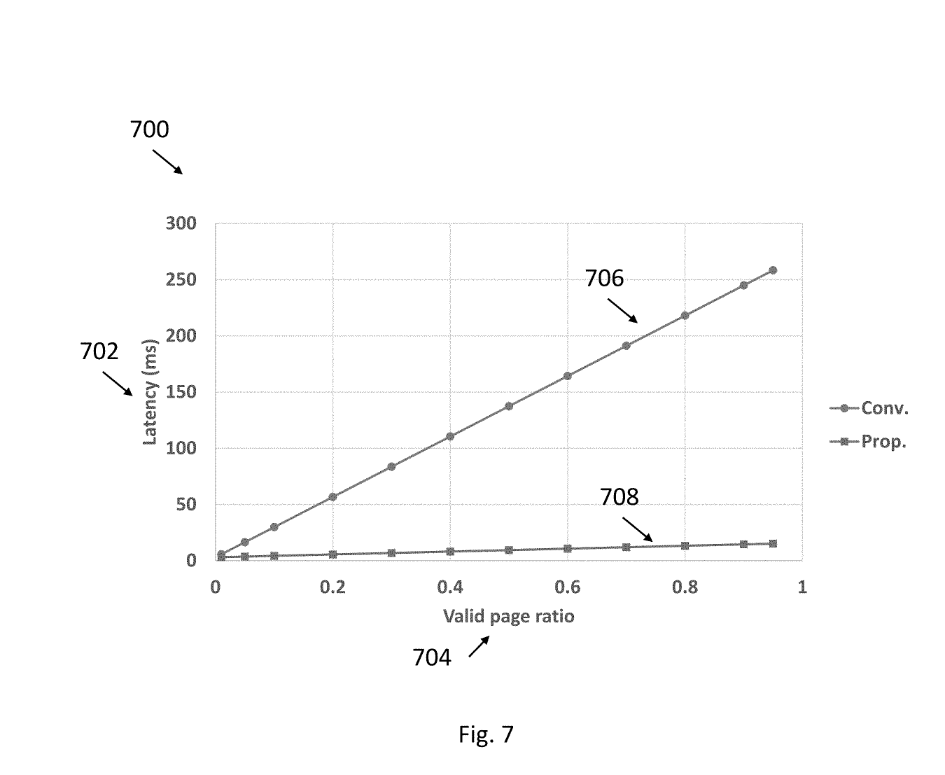

FIG. 7 shows a comparison of the garbage collection latency overhead of a conventional system and of a proposed system with varying valid page ratio. Specifically, FIG. 7 shows a graph 700 of the garbage collection latency 702 (in ms) over the valid page ratio 704 of pages in the block in the NAND flash chip that undergoes garbage collection, for a conventional system 706 and for an exemplary proposed system 708. The graph shows that as the valid page ratio increases, the latency overhead in the proposed system is significantly reduced.

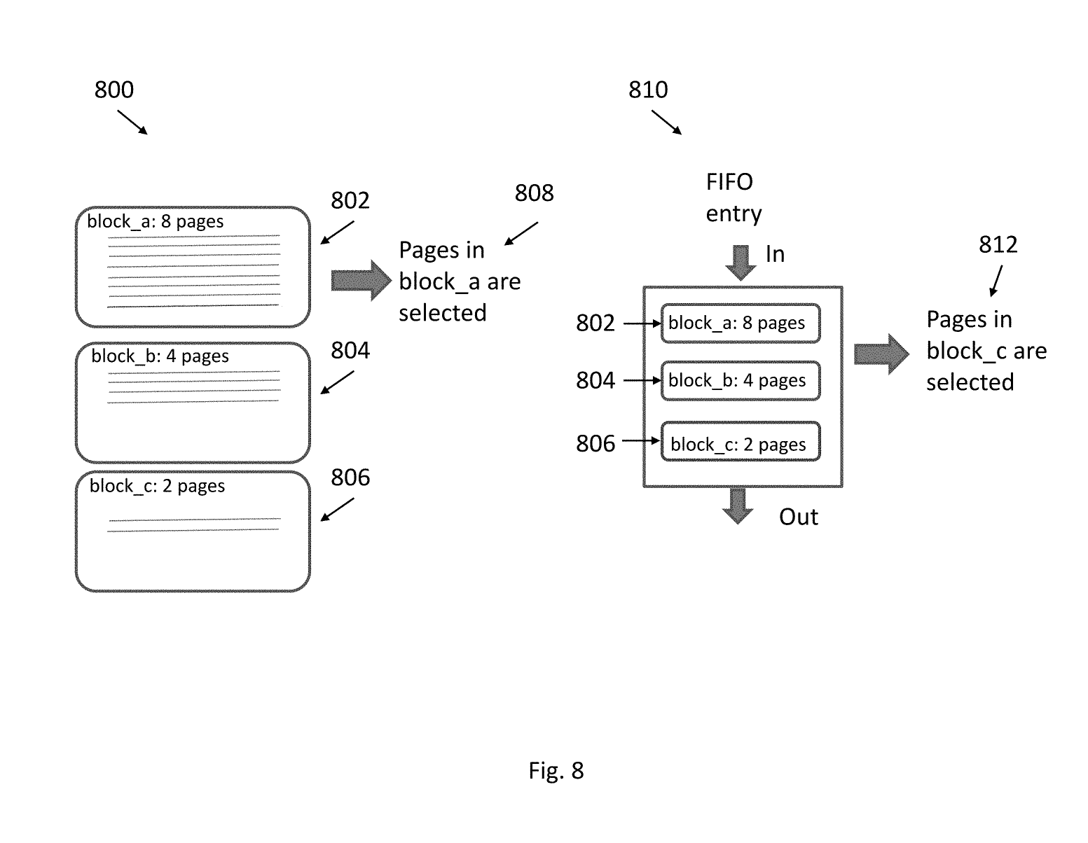

As discussed above, because the SCM is non-volatile, there is no requirement to flush the garbage collection valid data from the second region R2 (404) of the SCM to the NAND flash chip 308 immediately. The data that will eventually be evicted can be determined based on an eviction policy. FIG. 8 illustrates two exemplary eviction policies. Specifically, under a “fair selection” (greedy) eviction policy 800, the pages to be evicted are selected from the block containing the most pages. For example, as shown in FIG. 8, block_a 802 has eight pages, block_b 804 has four pages, and block_c has 2 pages. According to the “fair selection” eviction policy, the pages in block_a 802 can be selected for eviction 808. Under a first-in-first-out (“FIFO”) eviction policy 810, the block owning the oldest data is selected. Once the block is selected, then all pages in the selected block are evicted. For example, if block_c 806 contains a page with the oldest data among all pages in all blocks in the SCM, then under the FIFO eviction policy, the pages in block_c 806 can be selected for eviction 812.

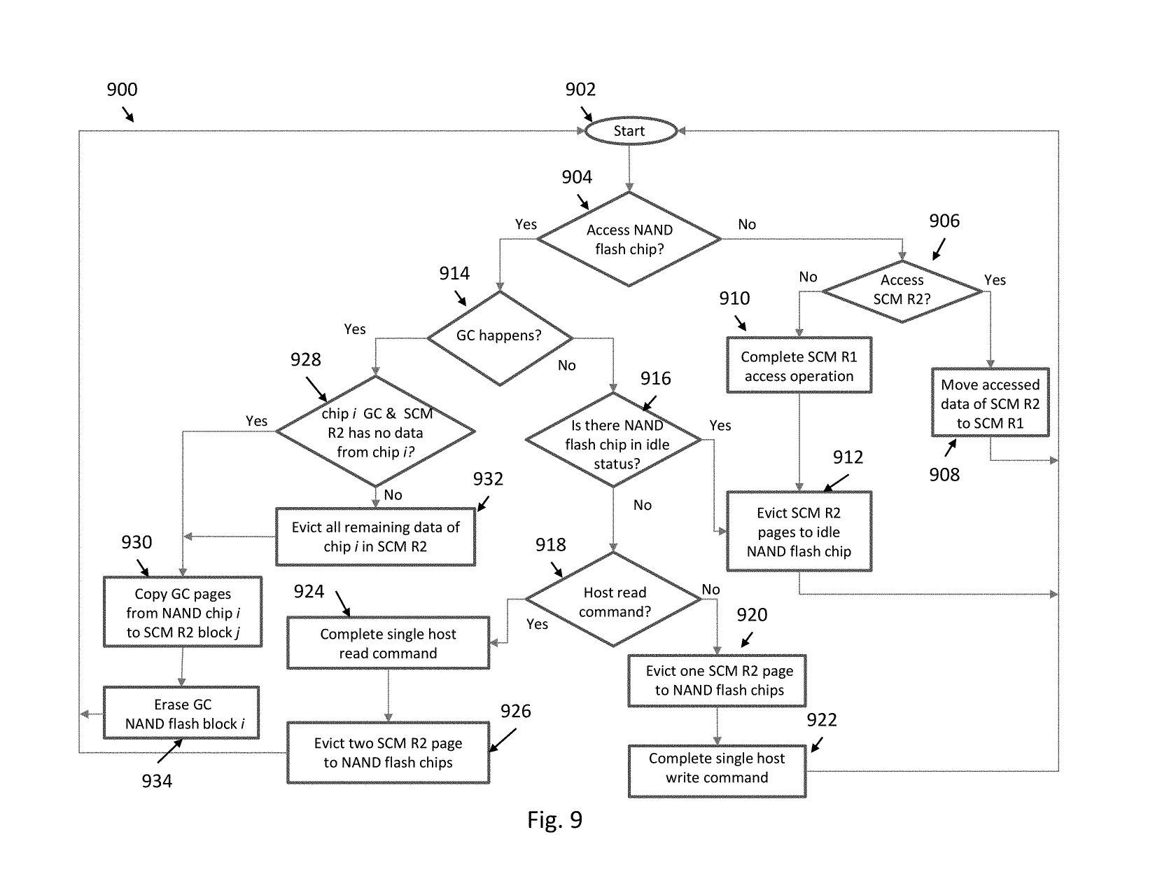

FIG. 9 shows an exemplary flow chart of a method for reducing worst case latency of NAND flash-based SSDs, according to aspects of the disclosure. Specifically, the SSD controller can wait for a host command 902. The method can determine whether the received host command requires access to a NAND flash chip 904. If the host command does not require access to the NAND flash chip, then the method can check whether the host command requires access to the second region R2 906. If it does, the requested data is moved from the second region R2 to the first region R1 of the SCM 908. If the host command does not require access to the second region R2, the host command is completed after the first region R1 is accessed 910. Then the corresponding pages are evicted from the second region R2 to the NAND flash chip, which is in an idle state, since the host command does not require access to it 912.

If the host command requires access to a NAND flash chip, then the method can check whether a garbage collection operation is occurring at the NAND flash chip 914. If there is no garbage collection operation, the method can check whether there is a NAND flash chip in an idle status 916. If there is an idle NAND flash chip, then pages from the second region R2 can be evicted to the NAND flash chip 912. If there is no idle NAND flash chip, then the method can check whether the received host command is a read command or a write command 918. If the host command is a write command, then one page from the second region R2 can be evicted to the NAND flash chips 920 and the write command can complete 922. If the host command is a read command, then the read command can complete 924 and two pages from the second region R2 can be evicted to the NAND flash chips 926.

If there is a garbage collection operation when the host operation requires access to the NAND flash, the method can check whether a particular NAND flash chip, e.g., chip i, undergoes the garbage collection operation and whether the second region R2 (404) has any data from the particular NAND flash chip, e.g., chip i, 928. If chip i undergoes a garbage operation and the second region R2 has no data from chip i, then all valid pages from the victim block can be copied from chip i to the second region R2 930. In the other case, the method can evict all remaining data of chip i in the second region R2 932, before all valid pages from the victim block can be copied from chip i to the second region R2 930. Check 928 is a condition that can be used to set the deadline of evicting the garbage collection data in SCM R2 region (404). The garbage collected data in the second region R2 (404) is the static data that can be eventually written to the NAND flash memory. The second region R2 (404) can provide a temporary space for completing quickly the garbage collection process. If condition 928 is true, this can mean that chip i can still have data pages in second region R2 when chip i triggers the garbage collection again. In this case, the SSD controller can evict the data pages in the second region R2 from chip i because in the worst case, the second region R2 region can overflow if no deadline condition is not set. Finally, the method can erase the victim block 934.

Those of skill in the art would appreciate that the various illustrations in the specification and drawings described herein can be implemented as electronic hardware, computer software, or combinations of both. To illustrate this interchangeability of hardware and software, various illustrative blocks, modules, elements, components, methods, and algorithms have been described above generally in terms of their functionality. Whether such functionality is implemented as hardware, software, or a combination depends upon the particular application and design constraints imposed on the overall system. Skilled artisans can implement the described functionality in varying ways for each particular application. Various components and blocks can be arranged differently (for example, arranged in a different order, or partitioned in a different way) all without departing from the scope of the subject technology.

Furthermore, an implementation of the communication protocol can be realized in a centralized fashion in one computer system, or in a distributed fashion where different elements are spread across several interconnected computer systems. Any kind of computer system, or other apparatus adapted for carrying out the methods described herein, is suited to perform the functions described herein.

A typical combination of hardware and software could be a general purpose computer system with a computer program that, when being loaded and executed, controls the computer system such that it carries out the methods described herein. The methods for the communications protocol can also be embedded in a computer program product, which comprises all the features enabling the implementation of the methods described herein, and which, when loaded in a computer system is able to carry out these methods.

Computer program or application in the present context means any expression, in any language, code or notation, of a set of instructions intended to cause a system having an information processing capability to perform a particular function either directly or after either or both of the following a) conversion to another language, code or notation; b) reproduction in a different material form. Significantly, this communications protocol can be embodied in other specific forms without departing from the spirit or essential attributes thereof, and accordingly, reference should be had to the following claims, rather than to the foregoing specification, as indicating the scope of the invention.

The communications protocol has been described in detail with specific reference to these illustrated embodiments. It will be apparent, however, that various modifications and changes can be made within the spirit and scope of the disclosure as described in the foregoing specification, and such modifications and changes are to be considered equivalents and part of this disclosure.

1. A method for reducing latency in a non-volatile memory comprising a flash memory and a storage class memory, the method comprising:
providing a first region and a second region in the storage class memory;
receiving, by the non-volatile memory, a first command from a host in communication with the non-volatile memory;
determining whether the first command requires access to a block in the flash memory;
determining whether the first command requires access to the second region in the storage class memory, when the first command does not require access to the block in the flash memory; and
moving data accessed by the first command from the second region in the storage class memory to the first region in the storage class memory, when the first command requires access to the second region in the storage class memory.

2. The method of claim 1, wherein when the first command does not require access to the second region in the storage class memory, the method further comprising:
accessing the first region in the storage class memory to execute the first command; and
evicting data from the second region in the storage class memory to the flash memory.

3. The method of claim 1, wherein when the first command requires access to the block in the flash memory, the method further comprising:
determining whether a garbage collection operation is executed in the flash memory; and
when the garbage collection operation is not executed:
determining whether the flash memory is in an idle state; and
evicting data from the second region in the storage class memory to the flash memory, when the flash memory is in the idle state.

4. The method of claim 3, further comprising:
determining whether the first command is at least one of a read command and a write command, when the flash memory is not in the idle state; and
when the first command is a write command:
evicting a data page from the second region in the storage class memory to the flash memory; and
executing the write command.

5. The method of claim 4, wherein when the first command is a read command, the method further comprising:
executing the read command; and
evicting two data pages from the second region in the storage class memory to the flash memory.

6. The method of claim 3, wherein when the garbage collection operation is executed, the method further comprising:
copying valid pages from a first flash memory chip to the second region of the storage class memory; and
erasing a memory block in the first flash memory chip.

7. The method of claim 6, further comprising:
determining that at least one of the garbage collection operation is not executed on the first flash memory chip and the second region of the storage class memory has data from the first flash memory chip; and
evicting data from the first flash memory chip to the second region in the storage class memory.

8. The method of claim 1, further comprising evicting data from the second region of the storage class memory to the flash memory based on an eviction policy based on at least one of the number of pages in a block in the second region and the age of the pages in the block in the second region.

9. The method of claim 1, wherein the flash memory is a NAND flash memory and the NAND flash memory comprises a plurality of NAND flash memory chips.

10. The method of claim 1, wherein the storage class memory is at least one of a magnetoresistive random-access memory (“MRAM”), a phase-change memory (“PCM”), a resistive random-access memory (“ReRAM”), and a battery-backed DRAM.

11. A system comprising:
a flash memory;
a storage class memory, comprising a first region and a second region; and
a memory controller in communication with a host, the flash memory, and the storage class memory, the memory controller configured to:
receive a first command from the host;
determine whether the first command requires access to a block in the flash memory;
determine whether the first command requires access to the second region in the storage class memory, when the first command does not require access to the block in the flash memory; and
move data accessed by the first command from the second region in the storage class memory to the first region in the storage class memory, when the first command requires access to the second region in the storage class memory.

12. The system of claim 11, wherein when the first command does not require access to the second region in the storage class memory, the memory controller is further configured to:
access the first region in the storage class memory to execute the first command; and
evict data from the second region in the storage class memory to the flash memory.

13. The system of claim 11, wherein when the first command requires access to the block in the flash memory, the memory controller is further configured to:
determine whether a garbage collection operation is executed in the flash memory; and
when the garbage collection operation is not executed:
determine whether the flash memory is in an idle state; and
evict data from the second region in the storage class memory to the flash memory, when the flash memory is in the idle state.

14. The system of claim 13, wherein the memory controller is further configured to:
determine whether the first command is at least one of a read command and a write command, when the flash memory is not in the idle state; and
when the first command is a write command:
evict a data page from the second region in the storage class memory to the flash memory; and
execute the write command.

15. The system of claim 14, wherein when the first command is a read command, the memory controller is further configured to:
execute the read command; and
evict two data pages from the second region in the storage class memory to the flash memory.

16. The system of claim 13, wherein when the garbage collection operation is executed, the memory controller is further configured to:
copy valid pages from a first flash memory chip to the second region of the storage class memory; and
erase a memory block in the first flash memory chip.

17. The system of claim 16, further comprising:
determine that at least one of the garbage collection operation is not executed on the first flash memory chip and the second region of the storage class memory has data from the first flash memory chip; and
evict data from the first flash memory chip to the second region in the storage class memory.

18. The system of claim 11, wherein the memory controller is further configured to evict data from the second region of the storage class memory to the flash memory based on an eviction policy based on at least one of the number of pages in a block in the second region and the age of the pages in the block in the second region.

19. The system of claim 11, wherein the flash memory is a NAND flash memory and the NAND flash memory comprises a plurality of NAND flash memory chips.

20. The system of claim 11, wherein the storage class memory is at least one of a magnetoresistive random-access memory (“MRAM”), a phase-change memory (“PCM”), a resistive random-access memory (“ReRAM”), and a battery-backed DRAM.
